(19) United States
(12) Patent Application Publication
(10) Pub. No.: US 2026/0020275 A1
(43) Pub. Date: Jan. 15, 2026

(54) NITRIDE-BASED SEMICONDUCTOR DEVICE AND METHOD FOR MANUFACTURING THE SAME

(71) Applicant: INNOSCIENCE (ZHUHAI) TECHNOLOGY CO., LTD., GUANGDONG (CN)

(72) Inventors: Yang LIU, GUANGDONG (CN); Weixing DU, GUANGDONG (CN); Jheng-Sheng YOU, GUANGDONG (CN); Ming-Hong CHANG, GUANGDONG (CN)

(73) Assignee: INNOSCIENCE (ZHUHAI) TECHNOLOGY CO., LTD., GUANGDONG (CN)

(21) Appl. No.: 18/994,606

(22) PCT Filed: Jul. 20, 2022
(86) PCT No.: PCT/CN2022/106760

§ 371 Date: Jan. 15, 2025

(51) Int. Cl. H10D 30/47; H10D 30/01; H10D 62/824; H10D 64/27; H10D 64/66; H10D 64/68

(52) U.S. Cl. CPC H10D 30/475; H10D 30/015; H10D 64/516; H10D 64/667; H10D 64/693; H10D 62/824

(57) ABSTRACT

A nitride-based semiconductor device includes a first nitride-based semiconductor layer, a second nitride-based semi-conductor layer, a doped nitride-based semiconductor layer, a nitride-based isolation layer, a gate electrode, and a passivation layer. The second nitride-based semiconductor layer is disposed on the first nitride-based semiconductor layer. The second nitride-based semiconductor layer has a bandgap higher than a bandgap of the first nitride-based semiconductor layer. The doped nitride-based semiconductor layer is disposed above the second nitride-based semiconductor and having a first width. The nitride-based isolation layer is disposed on the doped nitride-based semiconductor layer and has a second width less than the first width. The gate electrode disposed on the nitride-based isolation layer and has a third width greater than the second width. The passivation layer is disposed above the second nitride-based semiconductor layer and has a portion located between the doped nitride-based semiconductor layer and the gate electrode.

### FIELD OF THE DISCLOSURE

The present disclosure generally relates to a nitride-based semiconductor device. More specifically, the present disclosure relates to a nitride-based semiconductor device including a nitride-based isolation layer to reduce leakage current.

### BACKGROUND OF THE DISCLOSURE

In recent years, intense research on high-electron-mobility transistors (HEMTs) has been prevalent, particularly for high power switching and high frequency applications. III-nitride-based HEMTs utilize a heterojunction interface between two materials with different bandgaps to form a quantum well-like structure, which accommodates a two-dimensional electron gas (2DEG) region, satisfying demands of high power/frequency devices. In addition to HEMTs, examples of devices having heterostructures further include heterojunction bipolar transistors (HBT), heterojunction field effect transistor (HFET), and modulation-doped FETs (MODFET). However, during the manufacturing process of III-nitride devices, oxygen diffusion may cause a leakage current issue, degrading the electrical properties of the device. Therefore, there is a need to improve device performance regarding this issue.

### SUMMARY OF THE DISCLOSURE

In accordance with one aspect of the present disclosure, a semiconductor device is provided. The nitride-based semiconductor device includes a first nitride-based semiconductor layer, a second nitride-based semiconductor layer, a doped nitride-based semiconductor layer, a nitride-based isolation layer, a gate electrode, and a passivation layer. The second nitride-based semiconductor layer is disposed on the first nitride-based semiconductor layer. The second nitride-based semiconductor layer has a bandgap higher than a bandgap of the first nitride-based semiconductor layer. The doped nitride-based semiconductor layer is disposed above the second nitride-based semiconductor and having a first width. The nitride-based isolation layer is disposed on the doped nitride-based semiconductor layer and has a second width less than the first width. The gate electrode disposed on the nitride-based isolation layer and has a third width greater than the second width. The passivation layer is disposed above the second nitride-based semiconductor layer and has a portion located between the doped nitride-based semiconductor layer and the gate electrode and abutting against the nitride-based isolation layer.

In accordance with one aspect of the present disclosure, a method for manufacturing a semiconductor device is provided. The method includes steps as follows. A first nitride-based semiconductor layer is formed. A second nitride-based semiconductor layer is formed on the first nitride-based semiconductor layer. A doped nitride-based semiconductor layer is formed above the second nitride-based semiconductor layer. A nitride-based isolation layer is formed on the doped nitride-based semiconductor layer. A gate electrode is formed over the second nitride-based semiconductor layer. The nitride-based isolation layer is narrowed down such that the nitride-based isolation layer is narrower than the nitride-based isolation layer and the gate electrode. A passivation layer is formed to fill a recess between the nitride-based isolation layer and the gate electrode.

In accordance with one aspect of the present disclosure, a semiconductor device is provided. The nitride-based semiconductor device includes a first nitride-based semiconductor layer, a second nitride-based semiconductor layer, a doped nitride-based semiconductor layer, a gate electrode, and a nitride-based isolation layer. The second nitride-based semiconductor layer is disposed on the first nitride-based semiconductor layer. The second nitride-based semiconductor layer has a bandgap higher than a bandgap of the first nitride-based semiconductor layer. The doped nitride-based semiconductor layer is disposed on the second nitride-based semiconductor. The gate electrode is disposed on the nitride-based isolation layer. The nitride-based isolation layer is disposed between the doped nitride-based semiconductor layer and the gate electrode. Opposite side surfaces of the nitride-based isolation layer are recessed with respect to the edges of the doped nitride-based semiconductor layer and the gate electrode.

By the above configuration, even though at least one leakage current flows through an edge of the gate electrode, the leakage current cannot directly get into the doped nitride-based semiconductor layer. Moreover, since the nitride-based isolation layer is narrower than the doped nitride-based semiconductor layer and the gate electrode, the leakage current path from the gate electrode to the doped nitride-based semiconductor layer is lengthened so the equivalent resistivity to the leakage current path increases.

### BRIEF DESCRIPTION OF THE DRAWINGS

Aspects of the present disclosure are readily understood from the following detailed description when read with the accompanying figures. It should be noted that various features may not be drawn to scale. That is, the dimensions of the various features may be arbitrarily increased or reduced for clarity of discussion. Embodiments of the present disclosure are described in more detail hereinafter with reference to the drawings, in which:

FIG. 1A is a vertical cross-sectional view of a semiconductor device according to some embodiments of the present disclosure;

FIG. 1B is an enlarged vertical cross-sectional view of a region in FIG. 1A according to some embodiments of the present disclosure;

FIG. 2A, FIG. 2B, and FIG. 2C show different stages of a method for manufacturing a nitride-based semiconductor device according to some embodiments of the present disclosure;

FIG. 3 is a cross-sectional view of a semiconductor device according to some embodiments of the present disclosure;

FIG. 4 is a cross-sectional view of a semiconductor device according to some embodiments of the present disclosure;

FIG. 5 is a cross-sectional view of a semiconductor device according to some embodiments of the present disclosure; and

FIG. 6 is a cross-sectional view of a semiconductor device according to some embodiments of the present disclosure.

### DETAILED DESCRIPTION:

Common reference numerals are used throughout the drawings and the detailed description to indicate the same or similar components. Embodiments of the present disclosure will be readily understood from the following detailed description taken in conjunction with the accompanying drawings.

Spatial descriptions, such as “on,” “above,” “below,” “up,” “left,” “right,” “down,” “top,” “bottom,” “vertical,” “horizontal,” “side,” “higher,” “lower,” “upper,” “over,” “under,” and so forth, are specified with respect to a certain component or group of components, or a certain plane of a component or group of components, for the orientation of the component(s) as shown in the associated figure. It should be understood that the spatial descriptions used herein are for purposes of illustration only, and that practical implementations of the structures described herein can be spatially arranged in any orientation or manner, provided that the merits of embodiments of this disclosure are not deviated from by such arrangement.

Further, it is noted that the actual shapes of the various structures depicted as approximately rectangular may, in actual device, be curved, have rounded edges, have somewhat uneven thicknesses, etc. due to device fabrication conditions. The straight lines and right angles are used solely for convenience of representation of layers and features.

In the following description, semiconductor devices/dies/packages, methods for manufacturing the same, and the likes are set forth as preferred examples. It will be apparent to those skilled in the art that modifications, including additions and/or substitutions may be made without departing from the scope and spirit of the present disclosure. Specific details may be omitted so as not to obscure the present disclosure; however, the disclosure is written to enable one skilled in the art to practice the teachings herein without undue experimentation.

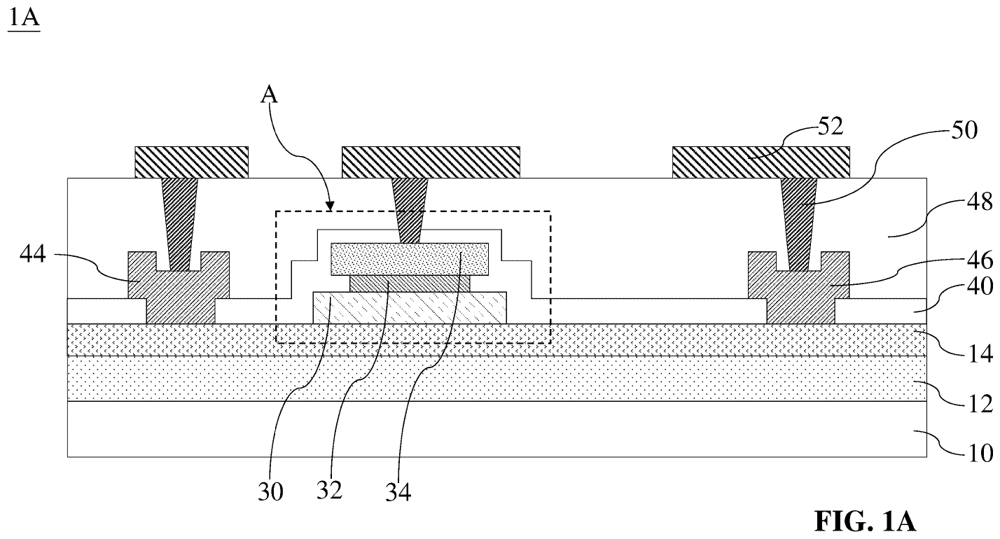

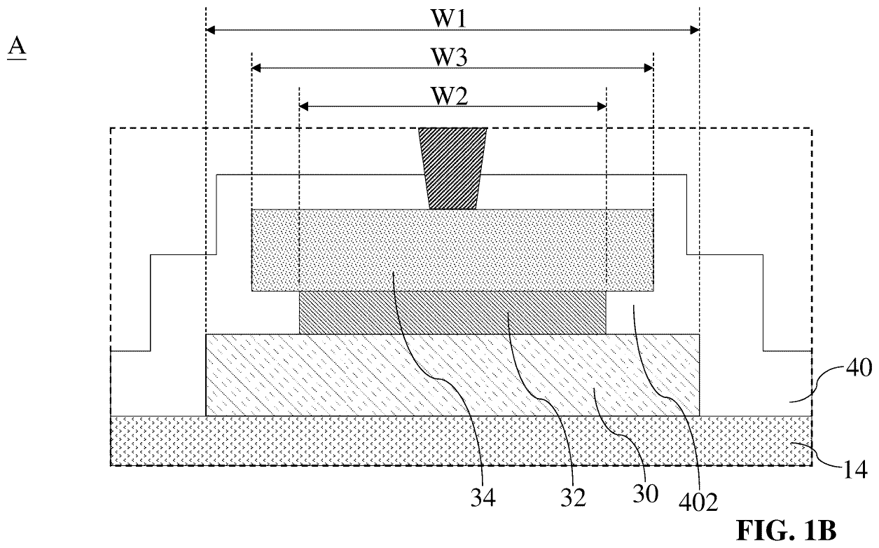

FIG. 1A is a vertical cross-sectional view of a semiconductor device 1A according to some embodiments of the present disclosure. The semiconductor device 1A includes a substrate 10, nitride-based semiconductor layers 12 and 14, a doped nitride-based semiconductor layer 30, a nitride-based isolation layer 32, a gate electrode 34, a passivation layer 40, conductive electrodes 44 and 46, a passivation layer 48, conductive vias 50, and a patterned conductive layer 52.

The substrate 10 may be a semiconductor substrate. The exemplary materials of the substrate 10 can include, for example but are not limited to, Si, SiGe, SiC, gallium arsenide, p-doped Si, n-doped Si, sapphire, semiconductor on insulator, such as silicon on insulator (SOI), or other suitable substrate materials. In some embodiments, the substrate 10 can include, for example, but is not limited to, group III elements, group IV elements, group V elements, or combinations thereof (e.g., III-V compounds). In other embodiments, the substrate 10 can include, for example but is not limited to, one or more other features, such as a doped region, a buried layer, an epitaxial (epi) layer, or combinations thereof.

In some embodiments, the semiconductor device 1A may further include a buffer layer. The buffer layer can be disposed over the substrate 10. The buffer layer can be disposed between the substrate 10 and the nitride-based semiconductor layer 12. The buffer layer can be configured to reduce lattice and thermal mismatches between the substrate 10 and the nitride-based semiconductor layer 12, thereby curing defects due to the mismatches/difference. The buffer layer may include a III-V compound. The III-V compound can include, for example but are not limited to, aluminum, gallium, indium, nitrogen, or combinations thereof. Accordingly, the exemplary materials of the buffer layer can further include, for example but are not limited to, GaN, AlN, AlGaN, InAlGaN, or combinations thereof.

In some embodiments, the semiconductor device 1A may further include a nucleation layer (not shown). The nucleation layer may be formed between the substrate 10 and the buffer layer. The nucleation layer can be configured to provide a transition to accommodate a mismatch/difference between the substrate 10 and a III-nitride layer of the buffer layer. The exemplary material of the nucleation layer can include, for example but is not limited to AlN or any of its alloys.

The nitride-based semiconductor layer 12 is disposed over the substrate 10 and the buffer layer. The nitride-based semiconductor layer 14 is disposed on the nitride-based semiconductor layer 12. The exemplary materials of the nitride-based semiconductor layer 12 can include, for example but are not limited to, nitrides or group III-V compounds, such as GaN, AlN, InN, InₓAl_{y}Ga_{(1-x-y)}N where x+y≤1, Al_{y}Ga_{(1-y)}N where y≤1. The exemplary materials of the nitride-based semiconductor layer 14 can include, for example but are not limited to, nitrides or group III-V compounds, such as GaN, AlN, InN, InₓAl_{y}Ga_{(1-x-y)}N where x+y≤1, Al_{y}Ga_{(1-y)}N where y≤1.

The exemplary materials of the nitride-based semiconductor layers 12 and 14 are selected such that the nitride-based semiconductor layer 14 has a bandgap (i.e., forbidden band width) greater than a bandgap of the nitride-based semiconductor layer 12, which causes electron affinities thereof different from each other and forms a heterojunction therebetween. For example, when the nitride-based semiconductor layer 12 is an undoped GaN layer having a bandgap of approximately 3.4 eV, the nitride-based semiconductor layer 14 can be selected as an AlGaN layer having bandgap of approximately 4.0 eV. As such, the nitride-based semiconductor layers 12 and 14 can serve as a channel layer and a barrier layer, respectively. A triangular well potential is generated at a bonded interface between the channel and barrier layers, so that electrons accumulate in the triangular well, thereby generating a two-dimensional electron gas (2DEG) region adjacent to the heterojunction. Accordingly, the semiconductor device 1A is available to include at least one GaN-based high-electron-mobility transistor (HEMT).

The doped nitride-based semiconductor layer 30 is disposed/stacked on/above the nitride-based semiconductor layer 14. The nitride-based isolation layer 32 is disposed/stacked on/above the doped nitride-based semiconductor layer 30. The gate electrode 34 is disposed/stacked on/above the nitride-based isolation layer 32. The nitride-based isolation layer 32 is located between the doped nitride-based semiconductor layer 30 and the gate electrode 34. The nitride-based isolation layer 32 can serve as isolation between the doped nitride-based semiconductor layer 30 and the gate electrode 34, such as element diffusion isolation or electrical isolation. For example, the nitride-based isolation layer 32 can block element diffusion from the doped nitride-based semiconductor layer 30 to the gate electrode 34. The element diffusion may occur at a high temperature process.

In the exemplary illustration of FIG. 1A, the semiconductor device 1A is an enhancement mode device, which is in a normally-off state when the gate electrode 34 is at approximately zero bias. Specifically, the doped nitride-based semiconductor layer 30 may create at least one p-n junction with the nitride-based semiconductor layer 14 to deplete the 2DEG region, such that at least one zone of the 2DEG region corresponding to a position below the corresponding the gate electrode 34 has different characteristics (e.g., different electron concentrations) than the rest of the 2DEG region and thus is blocked. Due to such mechanism, the semiconductor device 1A has a normally-off characteristic. In other words, when no voltage is applied to the gate electrode 34 or a voltage applied to the gate electrode 34 is less than a threshold voltage (i.e., a minimum voltage required to form an inversion layer below the gate electrode 34), the zone of the 2DEG region below the gate electrode 34 is kept blocked, and thus no current flows therethrough.

In some embodiments, the doped nitride-based semiconductor layer 30 can be omitted, such that the semiconductor device 1A is a depletion-mode device, which means the semiconductor device 1A in a normally-on state at zero gate-source voltage.

The doped nitride-based semiconductor layer 30 can be a p-type doped III-V semiconductor layer. The exemplary materials of the doped nitride-based semiconductor layer 30 can include, for example but are not limited to, p-doped group III-V nitride semiconductor materials, such as p-type GaN, p-type AlGaN, p-type InN, p-type AlInN, p-type InGaN, p-type AlInGaN, or combinations thereof. In some embodiments, the p-doped materials are achieved by using a p-type impurity, such as Be, Mg, Zn, Cd, and Mg. In some embodiments, the nitride-based semiconductor layer 12 includes undoped GaN and the nitride-based semiconductor layer 14 includes AlGaN, and the doped nitride-based semiconductor layer 30 is a p-type GaN layer which can bend the underlying band structure upwards and to deplete the corresponding zone of the 2DEG region, so as to place the semiconductor device 1A into an off-state condition.

The exemplary materials of the gate electrode 34 may include metals or metal compounds. The gate electrode 34 may be formed as a single layer, or plural layers of the same or different compositions. The exemplary materials of the metals or metal compounds can include, for example but are not limited to, W, Au, Pd, Ti, Ta, Co, Ni, Pt, Mo, TiN, TaN, metal alloys or compounds thereof, or other metallic compounds.

FIG. 1B is an enlarged vertical cross-sectional view of a region A in FIG. 1A according to some embodiments of the present disclosure. As shown in FIGS. 1A and 1B, the nitride-based isolation layer 32 is narrower than the doped nitride-based semiconductor layer 30 and the gate electrode 34, which results in improvement of working stability of the semiconductor device 1A.

During an operation, a gate electrode is biased. At the operation, defects in the gate electrode may result in leakage current. One of the most likely places for leakage current to occur is at edges of the gate electrode. Once at least one leakage current flows through the edges of the gate electrode, the leakage current might continue to flow downward, which reduces stability and performance.

To overcome such the issues, the nitride-based isolation layer 32 is sandwiched between the doped nitride-based semiconductor layer 30 and the gate electrode 34. Even though at least one leakage current flows through an edge of the gate electrode 34, the leakage current cannot directly get into the doped nitride-based semiconductor layer 30. Moreover, since the nitride-based isolation layer 32 is narrower than the doped nitride-based semiconductor layer 30 and the gate electrode 34, the leakage current path from the gate electrode 34 to the doped nitride-based semiconductor layer 30 is lengthened so the equivalent resistivity to the leakage current path increases. The increasing in the equivalent resistivity to the leakage current path can reduce probability of the leakage current flowing downward to the doped nitride-based semiconductor layer 30, thereby weakening the leakage current issue. A strong leakage current issue can increase strength of an electric field at edges of a gate electrode, so breakdown will occur across a device. Accordingly, by weakening the leakage current issue, the electric field can get modulated.

Specifically, the doped nitride-based semiconductor layer 30 has a width W1; the nitride-based isolation layer 32 has a width W2; the gate electrode has a width W3; and the relationship among the widths W1-W3 is W1>W2 and W3>W2. In the exemplary illustration of FIG. 1B, the relationship among the widths W1-W3 is W1>W3>W2. Accordingly, opposite side surfaces of the nitride-based isolation layer 32 are recessed with respect to the edges of the doped nitride-based semiconductor layer 30 and the gate electrode 34.

In some embodiments, the nitride-based isolation layer 32 has a thickness less than those of the doped nitride-based semiconductor layer 30 and the gate electrode 34. The thickness is designed to make the switch ratio of the semiconductor device 1A acceptable. In some embodiments, the exemplary materials of the nitride-based isolation layer 32 can include, for example but are not limited to, nitride, oxide, or combinations thereof. In some embodiments, the exemplary materials of the nitride-based isolation layer 32 can include, for example but are not limited to, AlN.

The passivation layer 40 is disposed above/on/over the nitride-based semiconductor layer 14. The passivation layer 40 can cover the doped nitride-based semiconductor layer 30, the nitride-based isolation layer 32, and the gate electrode 34. For example, the passivation layer 40 can cover side surfaces of the gate electrode 34. For example, the passivation layer 40 can cover a top surface of the gate electrode 34. The passivation layer 40 can extend into a gap between the doped nitride-based semiconductor layer 30 and the gate electrode 34. The passivation layer 40 can cover a top surface of the doped nitride-based semiconductor layer 30.

The passivation layer 40 has a portion 402 located between the doped nitride-based semiconductor layer 30 and the gate electrode 34. The portion 402 of the passivation layer 40 is in contact with the side surfaces of the nitride-based isolation layer 32. The portion 402 of the passivation layer 40 abuts against the nitride-based isolation layer.

In some embodiments, the width W2 of the nitride-based isolation layer 32 allows the passivation layer 40 to extend to entirely fill up the gap between the doped nitride-based semiconductor layer 30 and the gate electrode 34. That is, in case that the width W2 of the nitride-based isolation layer 32 is too small, the passivation layer 40 might not be deposited into the deep gap among the doped nitride-based semiconductor layer 30, the nitride-based isolation layer 32, and the gate electrode 34. In such the case, a void might be created, which will reduce the device performance. In some embodiments, a ratio of W1/W2 is greater than 1. In some embodiments, a ratio of W3/W2 is greater than 1.

In the exemplary illustration of FIG. 1B, the portion 402 of the passivation layer 40 forms a flat interface with the nitride-based isolation layer 32. In some embodiments, the nitride-based isolation layer 32 and the passivation layer 40 have different materials. In some embodiments, exemplary materials of the passivation layer 40 can include, for example but are not limited to, Si₃N₄, SiO₂, Al₂O₃, AlOₓN, SiO_{y}N, or combinations thereof. In some embodiments, exemplary materials of the passivation layer 40 can include, for example but are not limited to, Si₃N₄, SiO₂, A1₂O₃, AlOₓN, SiO_{y}N, or combinations thereof. In some embodiments, exemplary materials of the passivation layer 40 can include, for example but are not limited to, Si₃N₄, SiO₂, Al₂O₃, AlOₓN, SiO_{y}N, or combinations thereof. In some embodiments, exemplary materials of the passivation layer 40 can include, for example but are not limited to, Si₃N₄, SiO₂, Al₂O₃, AlOₓN, SiO_{y}N, or combinations thereof. In some embodiments, the nitride-based isolation layer has a conductivity greater than that of the passivation layer 40, in which such the selection can effectively block leakage current.

Referring to FIG. 1A, the conductive electrodes 44 and 46 are disposed on/over/above the nitride-based semiconductor layer 14. The doped nitride-based semiconductor layer 30, the nitride-based isolation layer 32, and the gate electrode 34 are located between the conductive electrodes 44 and 46. The conductive electrode 44 is closer to the doped nitride-based semiconductor layer 30 than the conductive electrode 46. The conductive electrode 44 is closer to the nitride-based isolation layer 32 than the conductive electrode 46. The conductive electrode 44 is closer to the gate electrode 34 than the conductive electrode 46.

In some embodiments, the electrode 44 can serve as a source electrode. In some embodiments, the electrode 44 can serve as a drain electrode. In some embodiments, the electrode 46 can serve as a source electrode. In some embodiments, the electrode 46 can serve as a drain electrode. In some embodiments, each of the conductive electrodes 44 and 46 can be called a source/drain (S/D) electrode, which means they can serve as a source electrode or a drain electrode, depending on the device design.

The conductive electrodes 44 and 46 can penetrate the passivation layer 40 to make contact with the nitride-based semiconductor layer 14. Each of the conductive electrodes 44 and 46 has a top portion covering the passivation layer 40. Each of the conductive electrodes 44 and 46 can be higher than the passivation layer 40.

In some embodiments, the conductive electrodes 44 and 46 can include, for example but are not limited to, metals, alloys, doped semiconductor materials (such as doped crystalline silicon), compounds such as silicides and nitrides, other conductor materials, or combinations thereof. The exemplary materials of the conductive electrodes 44 and 46 can include, for example but are not limited to, Ti, AlSi, TiN, or combinations thereof. The conductive electrodes 44 and 46 may be a single layer, or plural layers of the same or different composition. In some embodiments, the conductive electrodes 44 and 46 form ohmic contacts with the nitride-based semiconductor layer 14. The ohmic contacts can be achieved by applying Ti, Al, or other suitable materials to the conductive electrodes 44 and 46. In some embodiments, each of the conductive electrodes 44 and 46 is formed by at least one conformal layer and a conductive filling. The conformal layer can wrap the conductive filling. The exemplary materials of the conformal layer can include, for example but are not limited to, Ti, Ta, TiN, Al, Au, AlSi, Ni, Pt, or combinations thereof. The exemplary materials of the conductive filling can include, for example but are not limited to, AlSi, AlCu, or combinations thereof.

The passivation layer 48 covers the passivation layer 40 and the conductive electrodes 44 and 46. The passivation layer 48 can be formed for a protection purpose or for enhancing the electrical properties of the device (e.g., by providing an electrical isolation effect between/among different layers/elements). The passivation layer 48 can serve as a planarization layer which has a level top surface to support other layers/elements. In some embodiments, the passivation layer 48 can be formed as a thicker layer, and a planarization process, such as chemical mechanical polish (CMP) process, is performed on the passivation layer 48 to remove the excess portions, thereby forming a level top surface. The exemplary materials of the passivation layer 48 can include, for example but are not limited to, SiNₓ, SiOₓ, Si₃N₄, SiON, SiC, SiBN, SiCBN, oxides, nitrides, plasma-enhanced oxide (PEOX), or combinations thereof. In some embodiments, the passivation layer 48 can be a multi-layered structure, such as a composite dielectric layer of Al₂O₃/SiN, Al₂O₃/SiO₂, AlN/SiN, AlN/SiO₂, or combinations thereof.

The contact vias 50 are disposed in the passivation layer 48. The contact vias 50 extend longitudinally so as to electrically connect the gate electrode 34 and the conductive electrodes 44 and 46. Top surfaces of the contact vias 50 can be free from the coverage of the passivation layer 140. The exemplary materials of the contact vias 50 can include, but are not limited to, conductive materials, for example, metal or alloys.

The patterned conductive layer 52 is disposed on the passivation layer 48 and the contact vias 50. The patterned conductive layer 52 is in contact with the contact vias 50. The patterned conductive layer 52 may have metal lines, pads, traces, or combinations thereof, such that the patterned conductive layer 52 can form at least one circuit. The patterned conductive layer 52 may include a single film or multilayered film having Ag, Al, Cu, Mo, Ni, Ti, alloys thereof, oxides thereof, nitrides thereof, or combinations thereof.

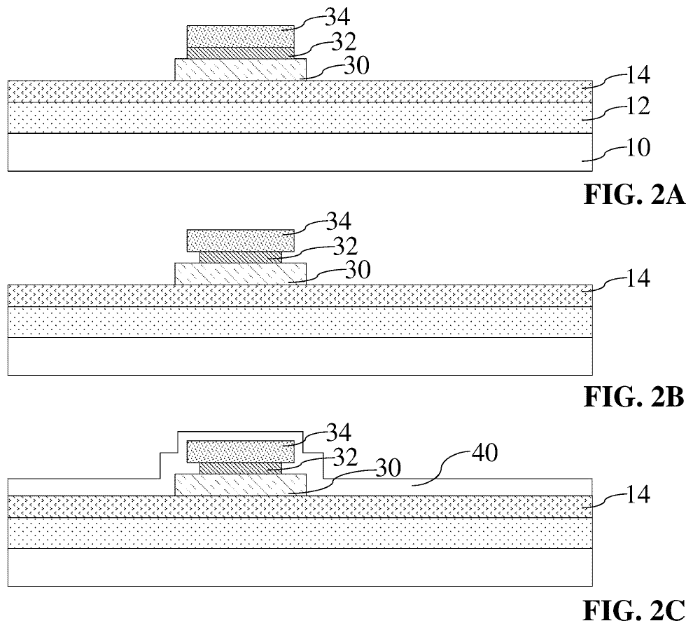

Different stages of a method for manufacturing the semiconductor device 1A are shown in FIG. 2A, FIG. 2B, and FIG. 2C as described below. In the following, deposition techniques can include, for example but are not limited to, atomic layer deposition (ALD), physical vapor deposition (PVD), chemical vapor deposition (CVD), metal organic CVD (MOCVD), plasma enhanced CVD (PECVD), low-pressure CVD (LPCVD), plasma-assisted vapor deposition, epitaxial growth, or other suitable processes.

Referring to FIG. 2A, a substrate 10 is provided. Nitride-based semiconductor layers 12 and 14 can be formed over the substrate 10 in sequence by using deposition techniques. Thereafter, a doped nitride-based semiconductor layer 30, a nitride-based isolation layer 32, and a gate electrode 34 can be formed over the nitride-based semiconductor layer 14.

The formation of the doped nitride-based semiconductor layer 30, the nitride-based isolation layer 32, and the gate electrode 34 includes deposition techniques and a patterning process. In some embodiments, the deposition techniques can be performed for forming a blanket layer, and the patterning process can be performed for removing excess portions thereof. In some embodiments, the patterning process can include photolithography, exposure and development, etching, other suitable processes, or combinations thereof.

In some embodiments, the doped nitride-based semiconductor layer 30 is wider than the nitride-based isolation layer 32 and the gate electrode 34. In some embodiments, the nitride-based isolation layer 32 and the gate electrode 34 have the same width. In some embodiments, the nitride-based isolation layer 32 and the gate electrode 34 are patterned in the same lithography process.

Referring to FIG. 2B, the nitride-based isolation layer 32 is narrowed down by a removing process. In some embodiments, the removing process includes a dry etching process, a wet etching process, or combinations thereof. After the removing process, the nitride-based isolation layer 32 is narrower the doped nitride-based semiconductor layer 30 and the gate electrode 34.

Referring to FIG. 2C, a passivation layer 40 is formed over the nitride-based semiconductor layer 14. The passivation layer 40 is formed to cover the doped nitride-based semiconductor layer 30, the nitride-based isolation layer 32, and the gate electrode 34. The passivation layer 40 can fill a recess/gap between the doped nitride-based semiconductor layer 30 and the gate electrode 34. The passivation layer 40 can fill a recess/gap among the doped nitride-based semiconductor layer 30, the nitride-based isolation layer 32, and the gate electrode 34.

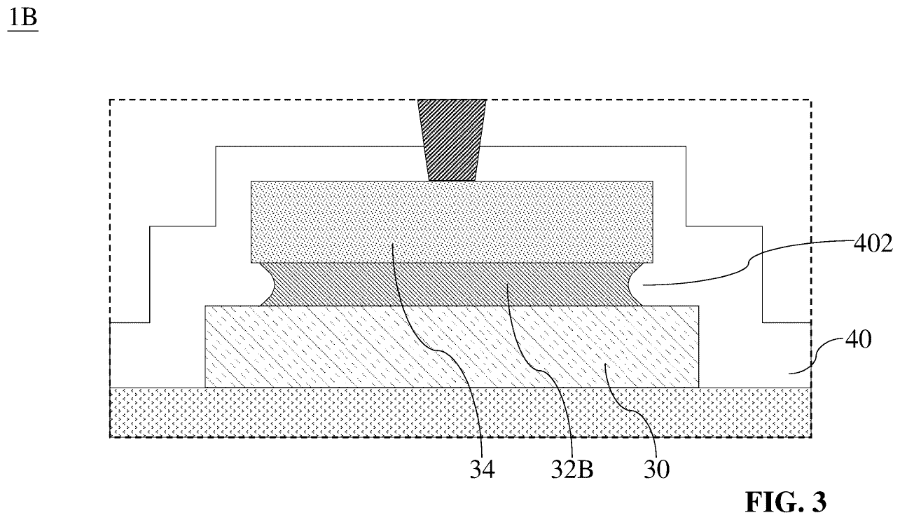

FIG. 3 is a cross-sectional view of a semiconductor device 1B according to some embodiments of the present disclosure. The semiconductor device 1B is similar to the semiconductor device 1A as described and illustrated with reference to FIGS. 1A and 1B, except that the nitride-based isolation layer 32 is replaced by a nitride-based isolation layer 32B.

The nitride-based isolation layer 32B has opposite curved sidewalls. The sidewalls of the nitride-based isolation layer 32B are recessed into its main body. Accordingly, the passivation layer 40 can have a portion 402 forming a curved interface with the nitride-based isolation layer 32B. The curved interface is recessed with respect to the nitride-based isolation layer 32B. The curved sidewalls of the nitride-based isolation layer 32B can make the portion 402 of the passivation layer 40 fill into gaps among the doped nitride-based semiconductor layer 30, the nitride-based isolation layer 32B, and the gate electrode 34 easily. To manufacture the semiconductor device 1B, the removing process applied for narrowing down nitride-based isolation layer 32B have recipes turned to be different than FIG. 2B, such as different etchant, temperature, or pressure.

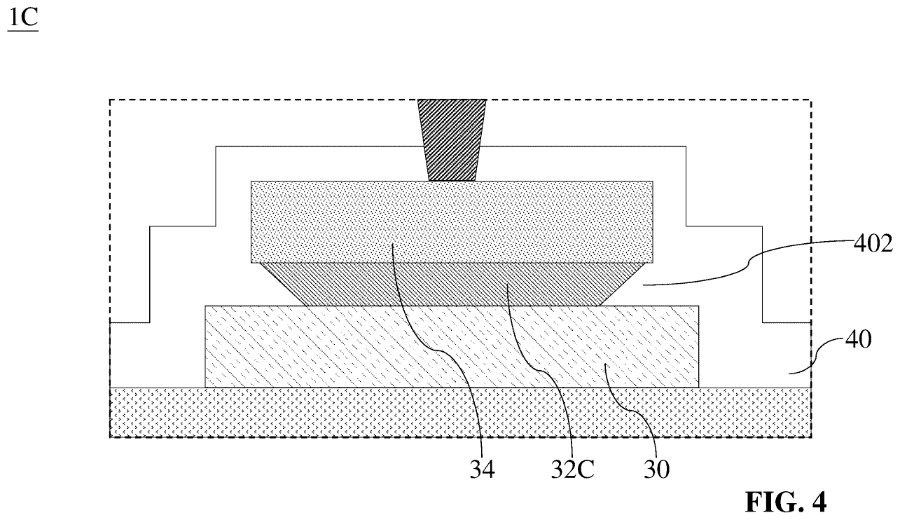

FIG. 4 is a cross-sectional view of a semiconductor device 1C according to some embodiments of the present disclosure. The semiconductor device 1C is similar to the semiconductor device 1A as described and illustrated with reference to FIGS. 1A and 1B, except that the nitride-based isolation layer 32 is replaced by a nitride-based isolation layer 32C.

The nitride-based isolation layer 32C has opposite oblique sidewalls. The nitride-based isolation layer 32C is tapered. The width of the nitride-based isolation layer 32C along the upward direction increases gradually. Accordingly, the passivation layer 40 can have a portion 402 forming an oblique interface with the nitride-based isolation layer 32C. The interface is oblique with respect to the nitride-based isolation layer 32C. The oblique sidewalls of the nitride-based isolation layer 32C can make the portion 402 of the passivation layer 40 fill into gaps among the doped nitride-based semiconductor layer 30, the nitride-based isolation layer 32C, and the gate electrode 34 easily. To manufacture the semiconductor device 1C, the removing process applied for narrowing down nitride-based isolation layer 32C have recipes turned to be different than FIG. 2B, such as different etchant, temperature, or pressure.

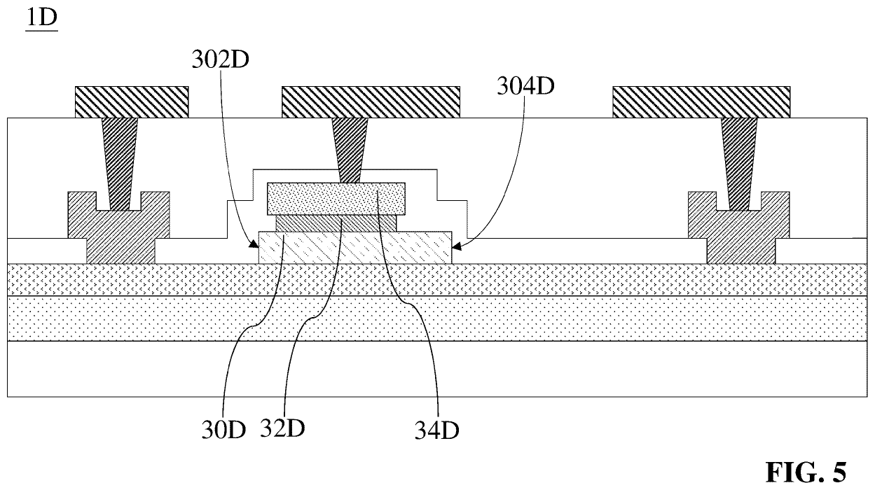

FIG. 5 is a cross-sectional view of a semiconductor device 1D according to some embodiments of the present disclosure. The semiconductor device ID is similar to the semiconductor device 1A as described and illustrated with reference to FIGS. 1A and 1B, except that the doped nitride-based semiconductor layer 30, the nitride-based isolation layer 32, and the gate electrode 34 are replaced by the doped nitride-based semiconductor layer 30D, the nitride-based isolation layer 32D, and the gate electrode 34D.

The doped nitride-based semiconductor layer 30D has side surfaces 302D and 304D which are opposite each other. A distance from the nitride-based isolation layer 32D to the side surface 302D is less than a distance from the nitride-based isolation layer 32D to the side surface 304D. Such the configuration is made in view of leakage current concern. The gate-drain side have the relatively stronger electrical field, so the distance relationship can effectively modulate the electrical field of the semiconductor device 1D.

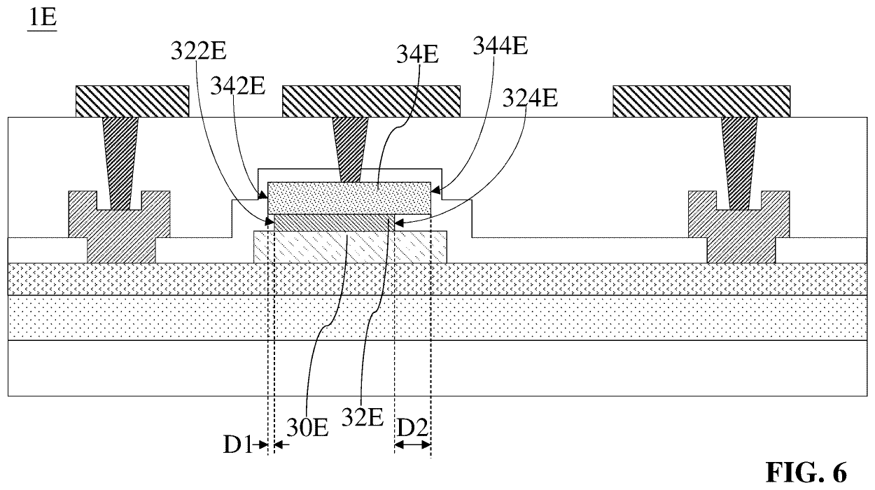

FIG. 6 is a cross-sectional view of a semiconductor device 1E according to some embodiments of the present disclosure. The semiconductor device 1E is similar to the semiconductor device 1A as described and illustrated with reference to FIGS. 1A and 1B, except that the doped nitride-based semiconductor layer 30, the nitride-based isolation layer 32, and the gate electrode 34 are replaced by the doped nitride-based semiconductor layer 30E, the nitride-based isolation layer 32E, and the gate electrode 34E.

The nitride-based isolation layer 32E has side surfaces 322E and 324E which are opposite each other. The gate electrode 34E has side surfaces 342E and 344E which are opposite each other. The side surface 322E of the nitride-based isolation layer 32E layer is spaced apart from the side surface 342E of the gate electrode 34E by a distance D1. The side surface 324E of the nitride-based isolation layer 32E layer is spaced apart from the side surface 344E of the gate electrode 34E by a distance D2. The distance D2 is greater than the distance D1. Such the configuration is made in view of leakage current concern. The gate-drain side have the relatively stronger electrical field, so the distance relationship can effectively modulate the electrical field of the semiconductor device 1E.

The embodiments were chosen and described in order to best explain the principles of the disclosure and its practical application, thereby enabling others skilled in the art to understand the disclosure for various embodiments and with various modifications that are suited to the particular use contemplated.

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. The term “substantially coplanar” can refer to two surfaces within micrometers of lying along a same plane, such as within 40 μm, within 30 μm, within 20 μm, within 10 μm, or within 1 μm of lying along the same plane.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. Further, it is understood that actual devices and layers may deviate from the rectangular layer depictions of the FIGS. and may include angles surfaces or edges, rounded corners, etc. due to manufacturing processes such as conformal deposition, etching, etc. There may be other embodiments of the present disclosure which are not specifically illustrated. The specification and the drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

1. A nitride-based semiconductor device, comprising:
a first nitride-based semiconductor layer;
a second nitride-based semiconductor layer disposed on the first nitride-based semiconductor layer, wherein the second nitride-based semiconductor layer has a bandgap higher than a bandgap of the first nitride-based semiconductor layer;
a doped nitride-based semiconductor layer disposed above the second nitride-based semiconductor and having a first width;
a nitride-based isolation layer disposed on the doped nitride-based semiconductor layer and having a second width less than the first width;
a gate electrode disposed on the nitride-based isolation layer and having a third width greater than the second width; and
a passivation layer disposed above the second nitride-based semiconductor layer and having a portion located between the doped nitride-based semiconductor layer and the gate electrode and abutting against the nitride-based isolation layer.

2. The semiconductor device of claim 1, wherein the portion of the passivation layer forms a flat interface with the nitride-based isolation layer.

3. The semiconductor device of claim 1, wherein the portion of the passivation layer forms a curved interface with the nitride-based isolation layer.

4. The semiconductor device of claim 3, wherein the curved interface is recessed with respect to the nitride-based isolation layer.

5. The semiconductor device of claim 1, wherein the nitride-based isolation layer has a conductivity greater than that of the passivation layer.

6. The semiconductor device of claim 1, wherein the nitride-based isolation layer has a thickness less than those of the doped nitride-based semiconductor layer and the gate electrode.

7. The semiconductor device of claim 1, wherein the passivation layer covers a top surface of the doped nitride-based semiconductor layer.

8. The semiconductor device of claim 7, wherein the passivation covers side surfaces of the gate electrode.

9. The semiconductor device of claim 8, wherein the passivation covers a top surface of the gate electrode.

10. The semiconductor device of claim 1, further comprising:
a source electrode and a drain electrode, wherein the doped nitride-based semiconductor layer, the nitride-based isolation layer, and the gate electrode are located between the source electrode and the drain electrode, wherein the source electrode is closer to the doped nitride-based semiconductor layer than the drain electrode.

11. The semiconductor device of claim 10, wherein the source electrode is closer to the nitride-based isolation layer than the drain electrode.

12. The semiconductor device of claim 1, wherein the doped nitride-based semiconductor layer has a first side surface and a second side surface which are opposite each other, and a distance from the nitride-based isolation layer to the first side surface is less than a distance from the nitride-based isolation layer to the second side surface.

13. The semiconductor device of claim 1, wherein a left side surface of the nitride-based isolation layer is spaced apart from a left side surface of the gate electrode by a first distance, and a right side surface of the nitride-based isolation layer is spaced apart from a right side surface of the gate electrode by a second distance which is greater than the first distance.

14. The semiconductor device of claim 1, wherein the nitride-based isolation layer comprises AlN.

15. The semiconductor device of claim 14, wherein the gate electrode comprises TiN.

16. A method for manufacturing a semiconductor device, comprising:
forming a first nitride-based semiconductor layer;
forming a second nitride-based semiconductor layer on the first nitride-based semiconductor layer;
forming a doped nitride-based semiconductor layer above the second nitride-based semiconductor layer;
forming a nitride-based isolation layer on the doped nitride-based semiconductor layer;
forming a gate electrode over the second nitride-based semiconductor layer;
narrowing down the nitride-based isolation layer such that the nitride-based isolation layer is narrower than the nitride-based isolation layer and the gate electrode; and
forming a passivation layer to fill a recess between the nitride-based isolation layer and the gate electrode.

17. The method of claim 16, wherein narrowing down the nitride-based isolation layer is performed after forming the gate electrode.

18. The method of claim 16, wherein narrowing down the nitride-based isolation layer is performed by using a wet etching process.

19. The method of claim 18, wherein narrowing down the nitride-based isolation layer is performed by using a dry etching process.

20. The method of claim 19, wherein narrowing down the nitride-based isolation layer is performed such that the nitride-based isolation layer has curved side surfaces.

21. A nitride-based semiconductor device, comprising:
a first nitride-based semiconductor layer;
a second nitride-based semiconductor layer disposed on the first nitride-based semiconductor layer, wherein the second nitride-based semiconductor layer has a bandgap higher than a bandgap of the first nitride-based semiconductor layer;
a doped nitride-based semiconductor layer disposed on the second nitride-based semiconductor;
a gate electrode disposed on the nitride-based isolation layer; and
a nitride-based isolation layer disposed between the doped nitride-based semiconductor layer and the gate electrode, wherein opposite side surfaces of the nitride-based isolation layer are recessed with respect to the edges of the doped nitride-based semiconductor layer and the gate electrode.

22. The semiconductor device of a claim 21, further comprising:
a passivation layer covering the second nitride-based semiconductor layer and having a portion in contact with the recessed side surfaces of the nitride-based isolation layer.

23. The semiconductor device of claim 22, wherein the nitride-based isolation layer has a conductivity greater than that of the passivation layer.

24. The semiconductor device of claim 22, wherein the nitride-based isolation layer has a thickness less than those of the doped nitride-based semiconductor layer and the gate electrode.

25. The semiconductor device of claim 22, wherein the passivation layer covers a top surface of the doped nitride-based semiconductor layer.
